(19) United States
(12) Patent Application Publication
(10) Pub. No.: US 2004/0091066 A1
(43) Pub. Date: May 13, 2004

(54) Apparatus and method for a carrier recovery

(76) Inventor: Reinhold Noe, Paderborn (DE)

Correspondence Address: LERNER AND GREENBERG, P.A., POST OFFICE BOX 2480, HOLLYWOOD, FL, 33022-2480, US

(21) Appl. No.: 10/698,062

(22) Filed: Oct. 29, 2003

(30) Foreign Application Priority Data
Oct. 31, 2002 (DE) 102 51 176.4

(51) Int. Cl. H03D 3/22; H04L 27/22

(52) U.S. Cl. 375/332

(57) ABSTRACT

An intradyne receiver provides a received intradyne signal X which comprises at least two, mutually phase-shifted, and N-ary phase shift keyed intradyne part signals Xk. Here N=2 for binary and N=4 for quaternary PSK. For carrier recovery purposes their frequency is multiplied by a factor of N in an intradyne frequency multiplier FM. After passing a lowpass filter TPY the filtered, frequency-multiplied intradyne signal is passed through an intradyne frequency divider IDF1, IDF2 with carrier intradyne signals C1, C2 as output signals that allow to demodulate the received intradyne signal X. The intradyne frequency divider undertakes more than one state change while changing the phase of the carrier intradyne signal by 2π/N. It can be formed as a regenerative intradyne frequency divider. When used for coherent optical data transmission this allows to tolerate comparatively large laser line widths.

### BACKGROUND OF THE INVENTION

1. Field of the Invention

The invention relates to an apparatus and a corresponding method for a carrier recovery, in particular for phase shift keyed signals in an intradyne receiver.

Coherent optical intradyne receivers, which have been described in IEEE J. Lightwave Techn. 10(1992)9, pp. 1290-1296, are particularly suited for information transmission with phase shift keying. On one hand, they are no homodyne receivers because the electrically processed intermediate frequency signals need not be equal to zero. On the other hand they are no heterodyne receivers because the intermediate frequency assumes a value, the absolute value of which is relatively small, typically less than the inverse of the symbol rate. Therefore the intradyne signal consists of at least two part signals which can for example represent real and imaginary part, respectively, of a complex intradyne signal. Its frequency which is the intermediate frequency can be positive or negative or equal to zero. In addition to the quaternary phase shift keying that is described in the above-cited state-of-the-art a binary optical phase shift keying is also possible. The general case is an N-ary phase shift keying, where the phase step number N tells how many phase steps exist. A particular problem in this context is the recovery of a carrier in order to allow for a synchronous demodulation. Usually a phase-locked loop is used for this purpose, as depicted in FIGS. 1 and 2 in the above-cited state-of-the-art. This has the disadvantage that the intradyne signal may have only a small linewidth. This linewith is given by the sum of the linewidths of transmitter laser and local oscillator laser.

### SUMMARY OF THE INVENTION

It is therefore an object of the invention to specify an apparatus and a corresponding method for a carrier recovery for phase shift keyed signals which tolerates a comparably large linewidth of an intradyne signal.

With the above and other objects in view there is provided, in accordance with the invention, a carrier recovery apparatus for a received intradyne signal that is phase shift keyed in N steps, where N is a phase step number, comprising:

an input for receiving the received intradyne signal;

a frequency multiplier for multiplying a frequency of the received intradyne signal by a factor of N, and thereby generating a frequency-multiplied intradyne signal;

a filter connected to the frequency multiplier, said filter filtering the frequency-multiplied intradyne signal to generate a filtered frequency-multiplied intradyne signal; and

an intradyne frequency divider connected to the filter, said intradyne frequency divider dividing the frequency of the filtered frequency-multiplied intradyne signal by a factor of N, thereby generating a carrier intradyne signal from the filtered frequency-multiplied intradyne signal. The intradyne frequency divider undertakes more than one state change while changing a phase of the carrier intradyne signal by 2π/N.

In accordance with an added feature of the invention, the intradyne frequency divider comprises:

a multi-frequency oscillator for generating a fundamental-frequency intradyne signal derivative having a fundamental frequency and a harmonic-frequency signal with a harmonic frequency being an N-fold multiple of the fundamental frequency;

a mixing unit for processing the filtered frequency-multiplied intradyne signal and the harmonic-frequency signal to generate a scalar product in which the frequency of the filtered frequency-multiplied intradyne signal has been translated by the N-fold of the fundamental frequency, wherein an absolute value of the fundamental frequency is so large that a scalar product can represent the filtered frequency-multiplied intradyne signal without loss of information;

a state machine, to which the scalar product is directed, said state machine dividing the frequency of the scalar product by N, thereby generating a frequency offset carrier signal; and

a multiplying unit for mixing the fundamental-frequency intradyne signal derivative and the frequency offset carrier signal, where the frequency of the frequency offset carrier signal is translated back by an amount equal to the fundamental frequency, thereby generating a carrier intradyne signal.

In accordance with a further feature of the invention, the intradyne frequency divider comprises at least one regenerative intradyne frequency divider.

In accordance with again an added feature of the invention, the regenerative intradyne frequency divider comprises:

a complex multiplier for multiplying an intradyne input signal of the intradyne frequency divider and a complex conjugate intradyne signal; and

a complex conjugator for subjecting the intradyne output signal of the complex multiplier to a complex conjugation before it is being fed back as a complex conjugate intradyne signal to the complex multiplier.

In accordance with again an additional feature of the invention, the regenerative intradyne frequency divider comprises:

a complex multiplier for multiplying an intradyne input signal of the intradyne frequency divider and a complex conjugate intradyne signal; and

a complex conjugator and a power raising unit cascaded with said complex conjugator in arbitrary order, wherein the intradyne output signal of the complex multiplier undergoes complex conjugation and is raised to a W-th power, W being a positive integer, before being fed back as a complex conjugate intradyne signal to the complex multiplier.

With the above and other objects in view there is also provided, in accordance with the invention, a carrier recovery method for a received intradyne signal that is phase shift keyed in N steps, where N is a phase step number, which comprises:

multiplying a frequency of the received intradyne signal by a factor N, thereby generating a frequency-multiplied intradyne signal from the received intradyne signal;

filtering the frequency-multiplied intradyne signal; and

dividing the frequency of the filtered frequency-multiplied intradyne signal by a factor N in an intradyne frequency divider, thereby generating a carrier intradyne signal from the filtered frequency-multiplied intradyne signal, in which process the intradyne frequency divider undertakes more than one state change while changing a phase of the carrier intradyne signal by 2π/N.

In accordance with again an added feature of the invention, the method comprises:

generating a fundamental-frequency intradyne signal derivative having a fundamental frequency and a harmonic-frequency signal with a harmonic frequency, the harmonic frequency being an N-fold multiple of the fundamental frequency;

processing the filtered frequency-multiplied intradyne signal and the harmonic-frequency signal to generate a scalar product in which the frequency of the filtered frequency-multiplied intradyne signal has been translated by the N-fold of the fundamental frequency, wherein an absolute value of the fundamental frequency is so large that the scalar product can represent the filtered frequency-multiplied intradyne signal without loss of information;

dividing the frequency of the scalar product by N, thereby generating a frequency offset carrier signal; and

mixing the fundamental-frequency intradyne signal derivative and the frequency offset carrier signal, so that the frequency of said frequency offset carrier signal is translated back by an amount equal to the fundamental frequency, thereby generating a carrier intradyne signal.

In accordance with again an additional feature of the invention, the method comprises carrying out regenerative intradyne frequency dividing.

In accordance with again another feature of the invention, the method comprises:

complex-multiplying an intradyne input signal, the frequency of which is to be regeneratively divided, and a complex conjugate intradyne signal; and

complex-conjugating the regeneratively frequency divided intradyne signal to generate the complex conjugate intradyne signal.

In accordance with again an additional feature of the invention, the method comprises comprises:

complex-multiplying an intradyne input signal, the frequency of which is to be regeneratively divided, and a complex conjugate intradyne signal; and

complex-conjugating and raising to a W-th power, W being a positive integer, of the regeneratively frequency divided intradyne signal to generate the complex conjugate intradyne signal.

The solution of the problem lies in multiplying the frequency of the intradyne signal by the phase step number N, filtering, in particular lowpass-filtering this frequency-multiplied intradyne signal, and feeding this filtered signal to a processing unit which divides the frequency by the phase step number N as a frequency division factor. In doing so, the processing unit undertakes more than one state change while changing the phase of the recovered carrier, which is also an intradyne signal, by 2π/N.

This can be accomplished by transponding the filtered signal into a higher frequency range where it can be represented by a single signal, which is then frequency-divided by a state-of the-art frequency divider by the phase step number N as a frequency division factor. The frequency-divided signal is then transponded back into the original frequency range by 1/N-th of the frequency by which it has been previously been transponded into the higher frequency range.

This can also be accomplished by using an intradyne frequency divider which is formed as a regenerative frequency divider and has a very simple structure.

This can also be accomplished by generating signals with new phases, using linear combinations of several part signals. All these control a finite state machine with many states, which serves as a frequency divider.

The two last embodiments have the advantage that all signal processing occurs in the baseband. All embodiments have the great advantage that a comparatively large linewidth of the received intradyne signal X is permitted. For a phase step number N=2 it may lie in the order of the 0.005-fold, and for a phase step number N=4 it may lie in the order of the 0.0005-fold of the symbol rate, respectively.

Other features which are considered as characteristic for the invention are set forth in the appended claims.

Although the invention is illustrated and described herein as embodied in an apparatus and method for a carrier recovery, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a schematic block diagram illustrating a system for optical information transmission using phase shift keying;

FIG. 2 is a schematic diagram showing carrier recovery in accordance with the invention;

FIG. 3 is a diagram of an intradyne frequency divider;

FIG. 4 is a diagram of a multi-frequency oscillator;

FIG. 5 is a diagram of a state machine;

FIG. 6 is a diagram of an alternative embodiment of a multi-frequency oscillator;

FIG. 7 is a diagram of a multiplying unit;

FIG. 8 is a diagram of an alternative embodiment of an intradyne frequency divider according to the invention;

FIG. 9 is a block diagram of a regenerative intradyne frequency divider;

FIG. 10 is a block diagram of an alternative embodiment of a regenerative intradyne frequency divider; and

FIG. 11 is a schematic of an optoelectronic hybrid OHY.

### DESCRIPTION OF THE PREFERRED EMBODIMENTS

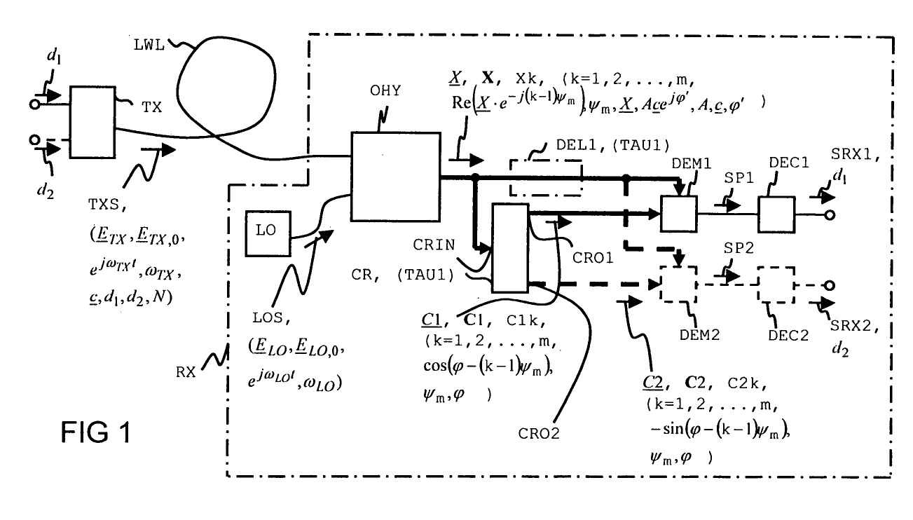

In FIG. 1 a system for optical information transmission using phase shift keying is shown. For a compact description complex signals will be used in the following. Also, proportionality factors will be neglected for simplicity. An optical transmitter TX emits an optical transmitted signal TXS having a transmitted field strength E_{TX}=cE_{TX,0}e^{jω}_{_{TX}}^{t}. Here E_{TX,0} is a scalar or vector proportional to a field strength, t is the time, and ω_{TX} is the optical transmitted signal angular frequency. For quaternary phase shift keying, corresponding to a phase step number N=4, the data symbol c equals c=d₁+jd₂, where d₁, d₂ are a first and a second binary signal, respectively, and j is the imaginary unit. First and second binary signal are here chosen as bipolar, i.e. they may both assume the values 1 and −1. For binary phase shift keying, corresponding to a phase step number N=2, the formula c=d₁+jd₂ can also be employed but the second binary signal d₂ must be set as d₂=0, so that it becomes functionless an that it holds de facto c=d₁.

After transmission through an optical fiber LWL the optical transmitted signal E_{TX} is directed to a receiver RX. Within the receiver RX it is superimposed in an optoelectronic hybrid OHY with an optical local oscillator signal LOS. It comes from a local oscillator LO and has a local oscillator field strength E_{LO}=E_{LO,0}e^{jω}_{_{LO}}^{t}, where E_{LO,0} is a scalar or vector proportional to the field strength and ω_{LO} is the angular frequency of the optical local oscillator LO. The optoelectronic hybrid OHY contains at least one optical directional coupler as well as photodetectors. It generates from the transmitted signal TXS and the local oscillator signal LOS a received intradyne signal X.

Groups of at least two part signals, which correspond to projections of a complex signal, that is represented in the complex plane, onto different axes which intersect in the origin of the complex plane, will be called intradyne signals here and in the following.

An intradyne signal A comprises a first to m-th intradyne part signal Ak with k=1,2, . . . ,m. Quantity m is the number of phases. Here it holds Ak=Re(A·e^{-j(k-1)ω}_{ₘ}), with ψ₂=π/2 for m=2, and with ψₘ=2π/m for m=3,4, . . . .

Further, A=[A1 A2 . . . Am]^{T} is the intradyne signal vector A, the m elements of which are the first to m-th intradyne part signals Ak. Since one representation can be transformed into the other, the denominations intradyne signal A, intradyne signal vector A and intradyne part signals Ak can alternatively be used for the description.

Of course intradyne part signals may also exist as differential or push-pull signals. A 4-phase intradyne signal, where the 4 intradyne part signals exist as single-ended signals, is also identical with a 2-phase intradyne signal, where both intradyne part signals exist as differential signals.

In order to obtain from an intradyne signal A a corresponding complex conjugate intradyne signal A * one must proceed as follows: For m=2 the sign of the second part signal A2 must be reversed, and in the case m=3 the part signals A2 and A3 must be exchanged.

The scalar product of two intradyne signal vectors A, B equals

$$\frac{m}{2} Re ( {\underline{AB}}^{*} )$$

according to the above definitions.

Due to the above definitions the sum A1+A2+ . . . +Am of first to m-th intradyne part signal Ak with k=1,2, . . . ,m is always identical to zero if it holds m=3,4, . . . . If in a practical system part signals exist which should be intradyne signals but do not fulfill this condition, then they can be forced to fulfill this conditions by subtracting their mean from each of them.

If necessary the number of phases m may be changed. This is accomplished by expressing the elements of a new intradyne signal by linear combinations of elementen of the intradyne signal which is to be converted. This operation is executed by amplifiers or attenuators acting as multipliers, and adders and subtractors. Let for example A be an intradyne signal vector, the elements of which are first and second intradyne part signals A1, A2 of an m=2-phase intradyne signal A. Let B be an intradyne signal vector, the elements of which are the erste to third intradyn part signal B1, B2, B3 of an m=3-phase intradyne signal B. Neglecting proportionality factors, one can write

$$B = [ \begin{matrix}1 & 0 \\ - 1 / 2 & \sqrt{3} / 2 \\ - 1 / 2 & - \sqrt{3} / 2\end{matrix} ] A and A = \frac{1}{3} [ \begin{matrix}2 & - 1 & - 1 \\ 0 & \sqrt{3} & - \sqrt{3}\end{matrix} ] B ,$$

which equations define conversions in both directions. These steps, which are not essential for the invention, are assumed to be possible and allowed for the realizations of alternative embodiments.

The m=2-phase product G=AB of two m=2-phase intradyne signals A, B is given by G1=A1·B1−A2·B2, G2=A1·B2+A2·B1. It can be implemented for instance by 4 real multipliers and one subtractor and one adder. The m=3-phas product G=AB of two m=3-phasie intradyne signal A, B is given by

$$G1 = \frac{2}{3} ( A1 \cdot B1 + A2 \cdot B3 + A3 \cdot B2 ) , G2 = \frac{2}{3} ( A3 \cdot B3 + A1 \cdot B2 + A2 \cdot B1 ) , G3 = \frac{2}{3} ( A2 \cdot B2 + A3 \cdot B1 + A1 \cdot B3 ) .$$

It can be implemented for instance by 9 real multipliers and 3 adders.

Let the intradyne signals, intradyne signal vectors and intradyne part signals that are used hitherto and in the following be defined in accordance with the above description.

The detected intradyne signal X is preferably modulated by binary or quaternary phase shift keying, because it holds X∝E_{LO}^{+E}_{TX}∝c(E_{LO,0}⁺E_{TX,0})e^{j(ω}_{_{TX}}^{-ω}_{_{LO}}^{)t}∝ce^{jφ′}, where ∝ means a proportionality. According to this one may as well write X=Xce^{jφ′}, where X is a positive proportionality constant, and φ′=(ω_{TX}−ω_{LO})t+arg(E_{LO,0}⁺E_{TX,0}) is a detected phase angle φ′ that is unknown for the time being. The detected intradyne signal carrier is the term Xe^{jφ′}, i.e., the detected intradyne signal X=Xce^{jφ′} divided by the data symbol c.

In a first and a second demodulator DEM1, DEM2 a first and a second scalar product SP1, SP2 are generated from an in-phase carrier intradyne signal vector C1 and a quadrature carrier intradyne signal vector C2, respectively, and the received intradyne signal vector X. The corresponding in-phase and quadrature carrier intradyne signals are C1=e^{jφ}, C2=je^{jφ}, respectively. According to this the in-phase carrier intradyne part signals Clk can be expressed by linear combinations of the quadrature carrier intradyne part signals C2k, and vice versa. First and second scalar product SP1, SP2 equal

$$SP1 = \frac{m}{2} Re ( \underline{X} \cdot {\underline{C1}}^{*} ) ∝ Re ( \underline{c} {ⅇ}^{j ( {ϕ}^{′} - ϕ )} ) and$$

$$SP2 = \frac{m}{2} Re ( \underline{X} \cdot {\underline{C2}}^{*} ) ∝ Im ( \underline{c} {ⅇ}^{j ( {ϕ}^{′} - ϕ )} ) ,$$

respectively. In the ideal case the carrier signal phase angle φ is equal to the signal phase angle φ′. In that case first and second scalar product SP1, SP2 are, according to SP1∝Re(c)=d₁, SP2∝Im(c)=d₂, proportional to first and second binary signal d₁, d₂, respectively. The carrier intradyne signals C1, C2 are provided by an inventive carrier recovery CR at a first and second carrier recovery output CRO1, CRO2, respectively. The received intradyne signal X is fed to the carrier recovery CR at a carrier recovery input CRIN. The signal delay in the carrier recovery CR, which constitutes a first signal delay TAU1, is taken into account in that the detected intradyne signal X, i.e. all detected intradyne part signals Xk, is being delayed in a first delay unit DELL by the same first signal delay TAU1 before being fed into the first and second demodulator DEM1, DEM2. First and second scalar product SP1, SP2 are directed to a first and second regenerator circuit DEC1, DEC2, at whose output a first and second regenerated binary signal SRX1, SRX2 is available, which corresponds in the absence of bit errors to the first and second binary signal d₁, d₂, respectively. The regenerator circuits DEC1, DEC2 may feature a common clock signal recovery. The second demodulator DEM2, the quadrature carrier intradyne signal C2 and the second regenerator circuit DEC2 can be left out if the phase step number N is chosen equal to 2 instead of 4.

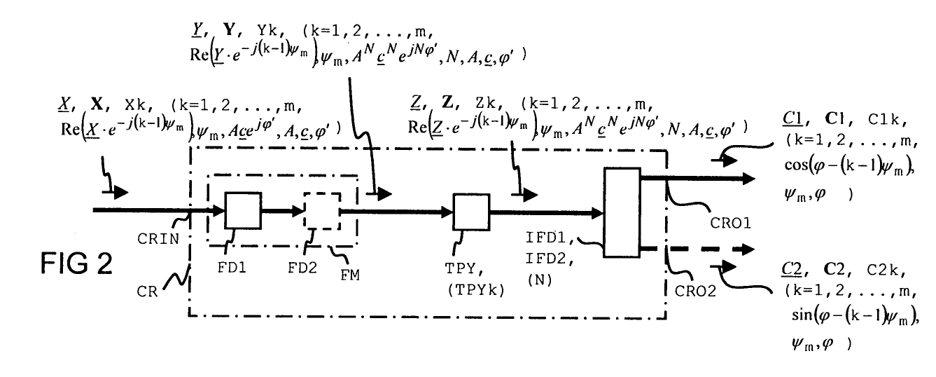

FIG. 2 shows an inventive carrier recovery CR. From the detected intradyne signal X, which is directed to the carrier recovery CR at a carrier recovery input CRIN, a frequency-multiplied intradyne signal Y is generated in an intradyne frequency multiplier FM, which is part of the carrier recovery CR. It multiplies the frequency of the received intradyne signal X. The frequency multiplication factor is equal to the number of phases N. In the simplest case Y∝X^{N} holds, i.e., the detected intradyne signal X is raised to the N-th power. Due to X^{N}∝c^{N}e^{jNφ′}∝e^{jNφ′} and c^{N}=const. the N-ary phase shift keying disappears therefore. For binary phase shift keying with N=2 the intradyne frequency multiplier FM features a first frequency doubler FD1 and it holds Y=X². For quaternary phase shift keying with N=4 a second frequency doubler FD2 is inserted inside the intradyne frequency multiplier FM behind the first frequency doubler FD1. It can be essentially identical to the first frequency doubler FD1. However, since for c=d₁+jd₂, i.e. for N=4, c^{N}=c⁴=−4 is a real negative number, whereas for c=d₁, i.e. for N=2, c^{N}=c²=1 is a real positive number, the second frequency doubler FD2 is formed in such a way that an inverter is placed at its output. This inverter takes care that in the case N=4 the frequency multiplied intradyne signal Y equals Y=−X⁴.

The frequency multiplication can be accomplished in several ways. Here we describe embodiments of the first frequency doubler FD1. When we write the received intradyne signal X as X=De^{jα} where D is the magnitude and α the phase, then for m=2 the detected intradyne part signals X1, X2 are X1=D cos α, X2=D sin α. According to the equations D² cos 2α=(D cos α)²−(D sin α)²=(X1)²−(X2)²=(X1+X2)·(X1−X2) and D²sin 2α=2(D cos α)(D sin α)=2·X1·X2=(½)((X1+X2)²−(X1−X2)²) one can express a first and a second frequency-doubled intradyne part signal XD1=2 cos ²α, XD2=D² sin 2α, which are parts of a frequency-doubled intradyne signal XD=X², by linear combinations of products of linear combinatios of the detected intradyne part signals X1, X2.

The situation for m=3 is similar. In that case the detected intradyne part signals X1, X2, X3 are X1=D cos α, X2=D cos(α−2π/3), X3=D cos(α−4π/3).

Using

$$[ \begin{matrix}cos α \\ sin α\end{matrix} ] = \frac{1}{3} [ \begin{matrix}2 & - 1 & - 1 \\ 0 & \sqrt{3} & - \sqrt{3}\end{matrix} ] [ \begin{matrix}cos α \\ cos ( α - 2 π / 3 ) \\ cos ( α - 4 π / 3 )\end{matrix} ] ,$$

cos 2α=cos²α−sin² α, sin 2α=2 cos α sin α,

$$[ \begin{matrix}cos 2 α \\ cos ( 2 α - 2 π / 3 ) \\ cos ( 2 α - 4 π / 3 )\end{matrix} ] = [ \begin{matrix}1 & 0 \\ - 1 / 2 & \sqrt{3} / 2 \\ - 1 / 2 & - \sqrt{3} / 2\end{matrix} ] [ \begin{matrix}cos 2 α \\ sin 2 α\end{matrix} ]$$

and cos α+cos(α−2π/3)+cos(α−4π/3)=0 one can for example derive

$$[ \begin{matrix}cos 2 α \\ cos ( 2 α - 2 π / 3 ) \\ cos ( 2 α - 4 π / 3 )\end{matrix} ] = \frac{4}{9} [ \begin{matrix}{cos}^{2} α - ( 1 / 2 ) {cos}^{2} ( α - 2 π / 3 ) - ( 1 / 2 ) {cos}^{2} ( α - 4 π / 3 ) \\ \frac{- cos αcos ( α - 2 π / 3 ) - cos α cos ( α - 4 π / 3 ) + 2 cos ( α - 2 π / 3 ) cos ( α - 4 π / 3 )}{- ( 1 / 2 ) {cos}^{2} α - ( 1 / 2 ) {cos}^{2} ( α - 2 π / 3 ) + {cos}^{2} ( α - 4 π / 3 ) } \\ \frac{+ 2 cos αcos ( α - 2 π / 3 ) - cos α cos ( α - 4 π / 3 ) - cos ( α - 2 π / 3 ) cos ( α - 4 π / 3 )}{- ( 1 / 2 ) {cos}^{2} α + {cos}^{2} ( α - 2 π / 3 ) - ( 1 / 2 ) {cos}^{2} ( α - 4 π / 3 ) } \\ - cos αcos ( α - 2 π / 3 ) + 2 cos αcos ( α - 4 π / 3 ) - cos ( α - 2 π / 3 ) cos ( α - 4 π / 3 )\end{matrix} ] ,$$

which means that for first to third frequency-doubled intradyne part signal XD1=D² cos 2α, XD2=D² cos(2α−2π/3), XD3=D² cos(2α−4π/3) it holds

$$XD1 = \frac{4}{9} ( {( X1 )}^{2} - ( 1 / 2 ) {( X2 )}^{2} - ( 1 / 2 ) {( X3 )}^{2} - X1 \cdot X2 - X1 \cdot X3 + 2 \cdot X2 \cdot X3 )$$

$$XD2 = \frac{4}{9} ( {( X3 )}^{2} - ( 1 / 2 ) {( X1 )}^{2} - ( 1 / 2 ) {( X2 )}^{2} - X1 \cdot X3 - X2 \cdot X3 + 2 \cdot X1 \cdot X2 ) . \\ XD3 = \frac{4}{9} ( {( X2 )}^{2} - ( 1 / 2 ) {( X1 )}^{2} - ( 1 / 2 ) {( X3 )}^{2} - X1 \cdot X2 - X2 \cdot X3 + 2 \cdot X1 \cdot X3 )$$

Further manipulations allow to obtain the equivalent expressions

$$XD1 = \frac{2}{3} ( {( X1 )}^{2} + 2 \cdot X2 \cdot X3 )$$

$$XD2 = \frac{2}{3} ( {( X3 )}^{2} + 2 \cdot X1 \cdot X2 ) . \\ XD3 = \frac{2}{3} ( {( X2 )}^{2} + 2 \cdot X1 \cdot X3 )$$

All these are or can be expressed as linear combinations of products of linear combinations of the detected intradyne part signals X1, X2, X3.

Similar relations allow it for example to generate from a detected intradyne signal X with a number of phases m=3 a frequency-doubled intradyne signal XD with m=2, or from a detected intradyne signal X with a number of phases m=2 a frequency-doubled intradyne signal XD with m=3.

In a next step the frequency-multiplied intradyne signal Y is filtered in a first filter TPY. The first filter TPY is preferentially a lowpass filter. Since the frequency-multiplied intradyne signal Y can, just as any intradyne signal, exhibit positive or negative frequency, the first filter TPY when formed as a lowpass filter takes care that only spectral components can pass where the absolute value of the frequency does not surpass a certain positive cutoff frequency. However, a lowpass filter is not the only possible embodyment of the first filter TPY. Rather, other embodiments such as a bandpass filter are also possible. In any case the first filter TPY limits the bandwidth and thereby eliminates noise to a substantial degree. The first filter TPY exhibits a first to m-th part filter TPYk, in which the first to m-th frequency-multiplied intradyne part signal Yk is filtered. First to m-th part filters TPYk are preferably chosen identically. It is useful to give them for example a bandwidth or cutoff frequency equal to the 0.01- to 0.25-fold of the symbol clock frequency. If the first filter TPY is formed as a lowpass filter then also all part filters TPYk are formed as lowpass filters. The output signal of the first filter TPY is a filtered intradyne signal Z, which exhibits a first to m-th filtered intradyne signal Zk. Due to the function of the first filter TPY the filtered intradyne signal Z generally differs from the frequency-multiplied intradyne signal Y. Neglecting amplitude noise and normalization factors it therefore holds Z∝e^{jNφ}. The phasen difference N(φ−φ′) between Z and Y is caused by the first filter TPY. Ideally the carrier signal phase angle φ equals the detected phase angle φ′.

In a last step the frequency of the filtered intradyne signal Z is divided by a factor equal to the phase step number N in a first, second or third intradyne frequency divider IFD1, IFD2, IFD3, to which the filtered intradyne signal Z is directed. The intradyne frequency divider IFD1, IFD2, IFD3 provides the in-phase and if applicable the quadrature carrier intradyne signal C1, C2, which are finally output at the first and if applicable second carrier recovery output CRO1, CRO2.

The intradyne frequency divider IFD1, IFD2, IFD3 undertakes more than one state change while changing the phase of the in-phase and if applicable of the quadrature carrier intradyne signal C1, C2 by 2π/N. Since phase changes of the carrier intradyne signal are roughly equal to the phase changes of the detected intradyne signal carrier Xe^{jφ′}, a phase change of the detected intradyne signal carrier Xe^{jφ′} by 2π/N will usually lead to more than one state change.

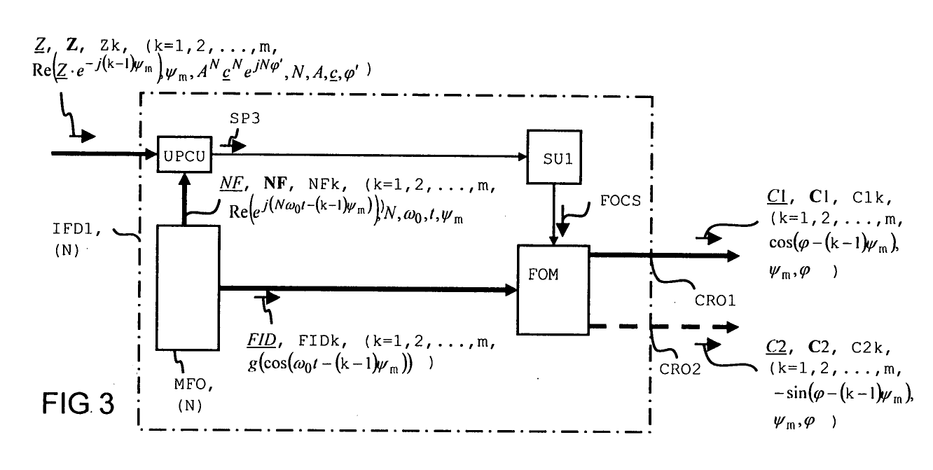

A first intradyne frequency divider IFD1 is shown as an exemplary embodiment in FIG. 3. Initially a third scalar product SP3 is formed in a mixing unit UPCU, which itself is formed as a linear combiner, from the filtered intradyne signal vector Z and a harmonic frequency intradyne signal vector NF. The harmonic frequency intradyne signal which corresponds to the harmonic frequency intradyne signal vector NF is NF=e^{jNω}_{₀}^{t}. It is provided by a multi-frequency oscillator MFO. The third scalar product SP3 is SP3∝Re(Z−NF*)∝Re(Z·e^{-jNω}_{₀}^{t})∝Re(e^{jN(φ-ω}_{₀}^{t)})=cos(N(φ−ω₀t)). During this operation the frequency of the filtered intradyne signal Z is translated by Nω₀. The fundamental frequency ω₀ is chosen such that the frequency N(dφ/dt−ω₀) of the term Z·e^{-jNω}_{₀}^{t} possesses always only a predetermined sign, so that the third scalar product SP3 represents the filtered intradyne signal Z without loss of information. Sufficient for this purpose is it if the absolute value |ω₀| of the fundamental frequency ω₀ is chosen so high that it is larger than the absolute value |dφ′/dt| of the temporal derivatife dφ′/dt of the detected phase angle φ′=(ω_{TX}−ω_{LO})t+arg(E_{LO,0}⁺E_{TX,0}). It is advantageous if the frequency N(dφ/dt−ω₀) of the term Z·e^{-jNω}_{₀}^{t} is chosen such that its absolute value is at least twice as high as the highest observable value of |dφ′/dt|. For exemple the absolute value of Nω₀/(2π) can be chosen to be on the order of the 0.2- . . . 1-fold of the symbol clock frequency.

The third scalar product SP3 is directed to a first state machine SU1 which acts as a divide-by-N frequency divider. At its ouput a frequency offset carrier signal FOCS is provided. It holds for example FOCS∝f(cos(φ′−ω₀t)). Here f is a first function, which preferably is formed to be monotonic. If the first state machine SU1 is formed as a frequency divider with a limited ouput bandwidth, as a regenerative frequency divider—consisting for N=2 of one and for N=4 of two cascaded regenerative divide-by-2 frequency dividers -, or as a static frequency divider with subsequent filter for the suppression of harmonics of the fundamental frequency ω₀, then the erste funktion f is for example the identity function. If the first state machine SU1 is formed as a static frequency divider then the first function f is at least approximately proportional to the sign (signum) function. The frequency offset carrier signal FOCS is directed to a multiplying unit FOM zugeführt, which acts as a mixer that undoes the function the mixing unit UPCU and provides at its output the in-phase and if applicable quadrature carrier intradyne signals C1=e^{jφ}, C2=je^{jφ}.

The multi-frequency oscillator MFO outputs also a signal FID which is a fundamental-frequency intradyne signal derivative FID. It exhibits the fundamental frequency ω₀ as its frequency and is also directed to the multiplying unit FOM. The fundamental-frequency intradyne signal derivative FID contains at least a first to m-th fundamental-frequency intradyne part signal derivative FIDk, which each is a second function g of a first to m-th fundamental frequency intradyne part signal Fk, respectively, that belongs to a fundamental-frequency intradyne signal F with F=e^{jω}_{₀}^{t}. Here it holds k=1,2, . . . ,m. The second function g can be in particular the identity functio or the sign function. It holds FIDk=g(cos(ω₀t−(k−1)ψₘ)).

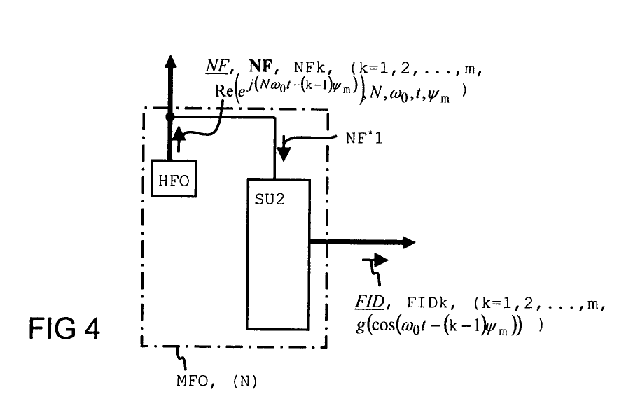

An embodiment of the multi-frequency oscillator MFO is shown in FIG. 4. It exhibits a harmonic-frequency oscillator HFO which generates the harmonic-frequency intradyne signal NF. The fundamental frequency ω₀ and hence also its N-fold Nω₀ are preferably chosen as constant. Therefore the necessary phase shifts (k−1)ψₘ of the harmonic-frequency intradyne part signals NFk and of the fundamental-frequency intradyne part signal derivatives FIDk can be generated for instance very simply be delay lines. For the generation of the necessary phase shifts (k−1)ψₘ of the harmonic-frequency intradyne part signals NFk a harmonic-frequency oscillator HFO formed as a ring oscillator is also well suited.

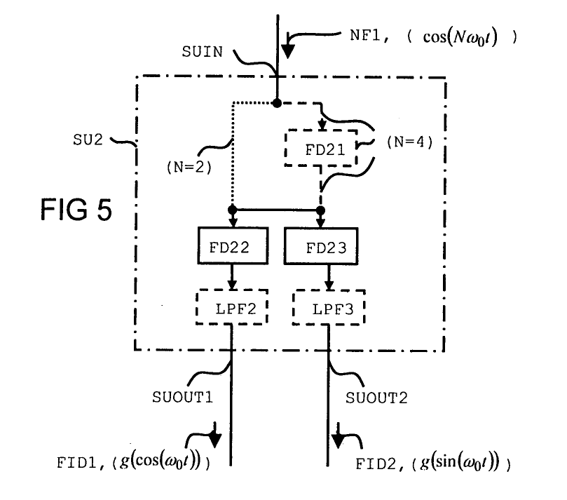

From the harmonic-frequency oscillator NFO the first harmonic-frequency intradyne part signal NF1=cos(Nω₀t) is for instance also directed to a state machine input SUIN of a second state machine SU2. The second state machine SU2 can be formed like the first state machine SU1, in which case the frequency offset carrier signal FOCS at the output of the first state machine SU1 corresponds to the first fundamental-frequency intradyne part signal derivative FID1=g(cos(ω₀t)) at an output of the second state machine SU2. The other second to m-th fundamental-frequency intradyne part signal derivatives FID2, FID3, . . . , FIDm are derived in the second state machine SU2 from the first fundamental-frequency intradyne part signal derivative FID1, for instance by the use of delay lines. Another embodiment of the second state machine SU2 which is possible for m=2 is shown in FIG. 5. For a phase step number N=4 the frequency of the signal which is directed to the state machine input SUIN is first divided by 2 in a first divide-by-2 frequency divider FD21. The output signal of the first divide-by-2 frequency divider FD21 or, in the case of a phase step number N=2, the signal fed to the state machine input SUIN, is directed to the inputs of a second and a third divide-by-2 frequency divider FD22, FD23 which exhibits opposed trigger polarities and which provide at their outputs the first and second fundamental-frequency intradyne part signal derivative FID1, FID2, respectively. These are passed on to the first or second state machine output SUOUT1, SUOUT2, possibly after having passed a second or third filter LPF2, LPF3, respectively, which are preferably formed as lowpass filters. The first fundamental-frequency intradyne part signal derivative FID1 can also be generated by a propagation delay from the second fundamental-frequency intradyne part signal derivative FID2, or vice versa, so that the second or third divide-by-2 frequency divider FD22, FD23 is not needed.

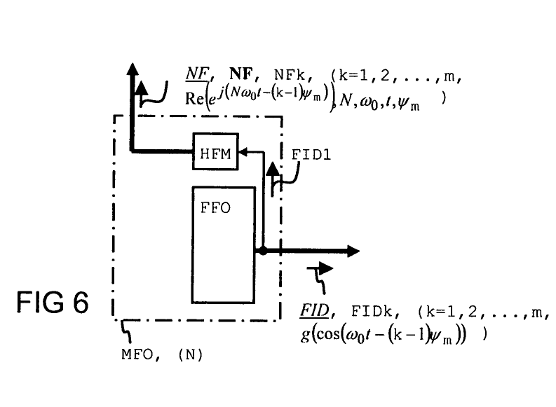

An alternative embodiment of the muulti-frequency oscillator MFO is shown in FIG. 6. It exhibits a fundamental-frequency oscillator FFO which generates the first to m-th fundamental-frequency intradyne part signal derivative FIDk. For instance, a ring oscillator with m stages, if it holds m>2, or with 4 stages, if it holds m=2, is suitable. At least the first harmonic-frequency intradyne part signal NF1 is obtained from at least one of the first to m-th fundamental-frequency intradyne part signal derivatives FIDk through a frequency multiplication by the factor N in an times-N frequency multiplier HFM. The second to m-th harmonic-frequency intradyne part signals NF2, NF3, . . . , NFm can also be derived from the first harmonic-frequency intradyne part signal NF1 by means of delay lines. As an alternative the times-N frequency multiplier HFM can be formed like the above-described intradyne frequency multiplier FM.

Harmonic frequency oscillator HFO and fundamental frequency oscillator FFO may also comprise dielectric or surface wave or other resonators with a high quality factor.

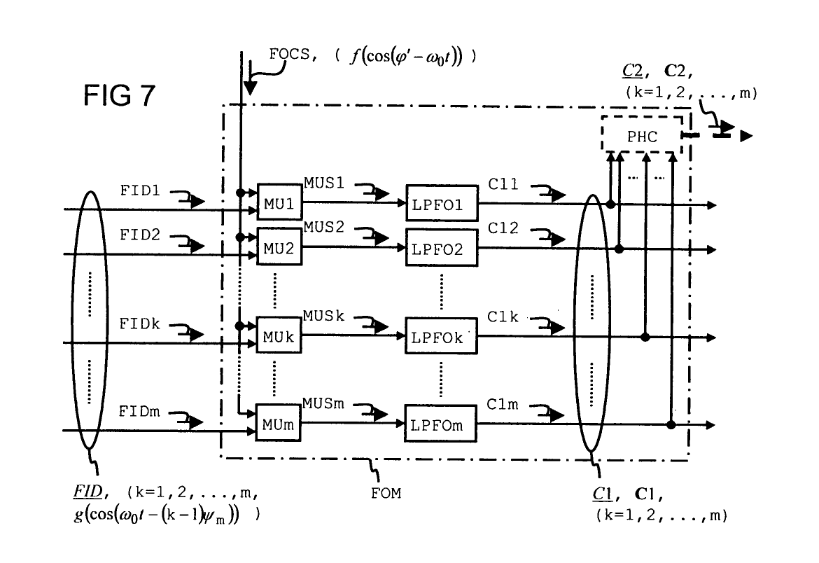

An embodiment of the multiplying unit FOM is shown in FIG. 7. The frequency offset carrier signal FOCS on one hand and a first to m-th fundamental frequency intradyne part signal derivative FIDk on the other hand are pairwise fed to inputs of a first to m-th multiplying element MUk, which provides at its output a first to m-th multiplying element output signal MUSk. First to m-th multiplying element output signal MUSk are MUSk=FOCS·FIDk∝f(cos(φ′−ω₀t))·g(cos(ω₀t−(k−1)ψₘ)) and are passed through a first to m-th carrier frequency filter LPFOk, that is preferably formed as a lowpass filter and provides at its output the first to m-th in-phase carrier intradyne part signal Clk, respectively, as components of the in-phase carrier intradyne signal C1. First to m-th carrier frequency filter LPFOk are preferably formed identically and possess, if formed as lowpass filters, a cutoff frequency that is large compared to the sum linewidth of the employed lasers, but smaller than twice the fundamental frequency ω₀ or smaller than the fundamental frequency ω₀ itself. It is advantageous if at least one of the first and second functions f, g are chosen equal to the identity functions. If they are formed this way then the in-phase carrier intradyne part signals Clk are as desired proportional to cos(φ−(k−1)ψₘ). The quadrature carrier intradyne signal C2 or more precisely its first to m-th quadrature carrier intradyne part signal C2k, which is proportional to sin(φ−(k−1)ψₘ), respectively, is formed from the in-phase carrier intradyne signal C1 in a phase converter PHC which itself is formed as a linear combiner of the first to m-th in-phase carrier intradyne part signal Clk. As an example, for m=2 the trivial linear combinations C21=C11, C22=−C11, and for m=3 the linear combinations C21=(1/\sqrt{3})(C12-C13), C22=(1/\sqrt{3})C13-C11), C23=(1/\sqrt{3})(C11-C12) can be employed.

In order to take care that the first intradyne frequency divider IFD1 according to FIG. 3 operates as described one provides a delay and/or phase adjustment and equalization, for example between the harmonic-frequency intradyne signal NF and the fundamental-frequency intradyne signal derivative FID on their paths to the multiplying unit FOM.

First to m-th carrier frequency filter LPFOk possess in their passband range—if they are formed as lowpass filters this range comprises the low frequencies—a group delay which one may wish to avoid in certain cases. On one hand, this is possible if one does not attenuate all frequencies above a certain cutoff frequency but only those harmonics of the fundamental frequency ω₀ which are actually generated and which actually interfere.

On the other hand, if first and second function f, g are both equal to the identity function, just a single harmonic will be generated, at 2ω₀, due to the identity

$$cos ( {ϕ}^{′} - {ω}_{0} t ) \cdot cos ( {ω}_{0} t - ( k - 1 ) {ψ}_{m} ) = \frac{1}{2} cos ( {ϕ}^{′} - ( k - 1 ) {ψ}_{m} ) + \frac{1}{2} cos ( {ϕ}^{′} - 2 {ω}_{0} t + ( k - 1 ) {ψ}_{m} ) .$$

If the first state machine SU1 is suitably formed, similar to or identical with the second state machine SU2, then it can generate, in addition to the frequency offset carrier signal FOCS that is proportional to cos(φ′−ω₀t), another frequency offset carrier signal that is proportional to sin(φ′−ω₀t). Likewise the multi-frequency oscillator MFO may generate, in addition to signals proportional to cos(ω₀t−(k−1)ψₘ), also signals proportional to sin(ω₀t−(k−1)/ψₘ), for example from the former ones by means of delay lines. Then it is sufficient to perform in the multiplying unit FOM just the operations

cos(φ′−ω₀t)·cos(ω₀t−(k−1)ωₘ)−sin(φ′−ω₀t)·sin(ω₀t−(k−1)ψₘ)=cos(φ′−(k−1)ψₘ)

which requires for each signal another multiplier and another subtractor erfordert. Since cos(φ′−(k−1)ψₘ) has no harmonics the first to m-th carrier frequency filter LPFOk can therefore be left out.

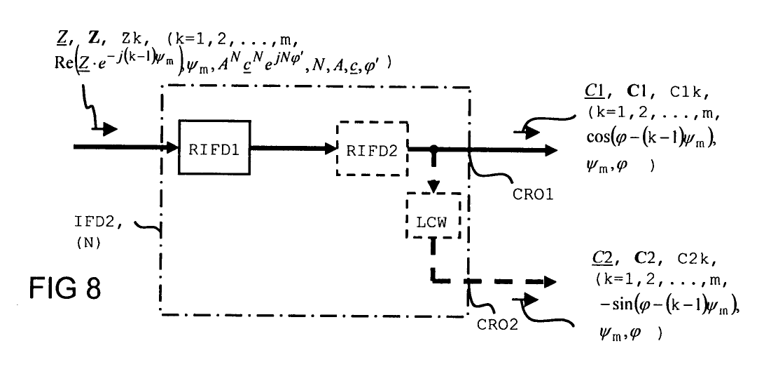

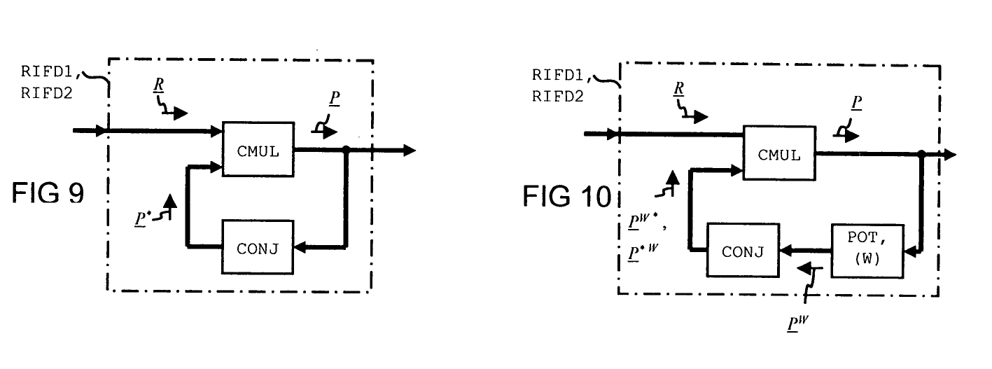

A second intradyne frequency divider IFD2, which may be employed as an alternative to the first intradyne frequency divider IFD1, is shown in FIG. 8. It possesses the advantage of needing no multi-frequency oscillator, nor any processing of signals having frequencies of the order Nω₀. Its frequency division factor or ratio is chosen equal to the phase step number N. The frequency of the filtered intradyne signal Z is divided, for N=2 in a first, and for N=4 in a first and, cascaded with the first, a second regenerative intradyne frequency divider RIFD1, RIFD2, respectiely. A first or second regenerative intradyne frequency divider RIFD1, RIFD2 is shown in FIG. 9. At its input it receives a frequency division intradyne signal R, i.e. an intradyne signal of which the frequency is to be divided. In the case of the first regenerative intradyne frequency divider RIFD1 this is the filtered intradyne signal. This implements the equation P:=r·R·P*, where r is a positive proportionality constant. For this purpose the frequency division intradyne signal R is directed to an input of the complex multiplier CMUL. The output signal of the complex multiplier CMUL is the frequency-divided intradyne signal P. It is not only provided by the regenerative intradyne frequency divider RIFD1, RIFD2 at its output. Rather it is also directed as a conjugate frequency-divided intradyne signal P*, after passing a complex conjugugator CONJ, to another input of the complex multipliers CMUL. The complex conjugator CONJ is hence placed in the feedback path of the regenerative intradyne frequency divider RFID1, RFID2. For R=e^{j2ψ} the only possible solution is P=e^{jψ}, i.e. phase angle and hence also frequency are halved. If, as shown in FIG. 10, the quantity P^{W} or P*^{W} is generated in a power raising unit POT, which raises its input signal to the W-th power, directly before or behind the complex conjugator CONJ from P or P*, respectively, then phase angle and frequency are divided by the frequency division factor W+1, since the quantity P^{W}*=P*^{W} is directed to the other input of the complex multiplier CMUL.

In total there are provided as many cascaded regenerative intradyne frequency dividers RFID1, RFID2 as necessary to make the product of all frequency division factors occuring in these regenerative frequency dividers RIFD1, RIFD2 equal to the number of phase steps N. For binary PSK, i.e. for N=2, the first intradyne frequency divider RFID1 with frequency division factor 2 according to FIG. 9 is sufficient. For QPSK, i.e. for N=4, it is formed to have a frequency division factor equal to 4 according to FIG. 10 with W=3. Else one cascades with it the second intradyne frequency divider RFID2, and first and second intradyne frequency divider RFID1, RFID2 are formed to have individual frequency division factors equal to 2, according to FIG. 9.

Further implementation details of the regenerative frequency divider RFID1, RFID2 are in the following discussed for the example of FIG. 9, but are also valid for FIG. 10 after performing the substitutions that are required to the power raising.

The proportionality constant r is chosen so that the magnitude |P| of the frequency-divided intradyne signal P is always constant and larger than zero. For this purpose the complex multiplier CMUL is for instance formed so that it is driven slightly into saturation if the desired magnitude |P| of the frequency-divided intradyne signal P occurs. In that case it holds r=|R|⁻¹. Alternatively to this a control of the proportionality constant r als a function of |P| or |P|² may be performed.

The number of phases m is chosen equal to 2 if the implementation effort is to be minimized. This is because the equation P:=r·R·P*, when split into real and imaginary parts, corresponds to the equations

P1=ReP:=r·Re·R·ReP+r·ImR·ImP=r·R1·P1+r·R2·P2,

P2=ImP:=r·ImR·ReP−r·ReR·ImP=r·R2·P1−r·R1·P2,

and these two equations are each implemented by two real multipliers and an adder and subtractor. The assignment:=means that the variable at the left hand side is continuously being assigned the expression at the right hand side, which may also contain the hitherto valid value of the variable at the left hand side. Re and Im mean real and imaginary parts, respectively, and real and imaginary parts likewise mean first and second part signal, respectively, of the respective m=2-phase intradyne signal.

The number of phases m can also be chosen equal to 3. In that case it is advantageous to process the frequency division intradyne signal R, the conjugate frequency division intradyne signal R*, the frequency-divided intradyne signal P and the conjugate frequency-divided intradyne signal P* each in such a way that the sum of the respective part signals equals zero. In that case the equation P:=r·R·P* is implemented according to the rules for complex conjugation and product forming given at the beginning of the description for m=3. According to those, 9 real multipliers and 3 adders can be employed.

If the equation P:=r·R·P* is not implemented time-continuously but time-discretely, it is not asymptotically stable. In the case of a time-discrete implementation it is useful to implement instead the equations P_{q}:=(½)(QQ_{q}+QQ_{q-1}), QQ_{q}:=r·R_{q}·P_{q-1}^{* which are asymptotically stable. Here QQ is an auxiliary intradyne signal and the indexing denotes the time instant at which a signal occurs, and the index q follows in time after the index q-}1.

In practice signals are often processed as differential signals. If this scheme is provided then the before-given numbers of phases m of 2 or 3 are doubled to become numbers of phases m equal to 4 or 6, respectively, but the functional principle stays unchanged.

A regenerative frequency divider RIFD1, RIFD2 possesses an infinite number of possible states because its function is analog. Hence it is a processing unit or state machine with an infinite number of possible states. Therefore the second intradyne frequency divider IFD2 undertakes more than one state change while changing the phase of a carrier intradyne signal C1, C2 by 2π/N.

For N=2 the output signal of the first and for N=4 the output signal of the second regenerative frequency divider RFID1, RFID2 is the in-phase carrier intradyne signal C1. The quadrature carrier intradyne signal C2 that is needed in the case N=4 is generated from it in yet another linear combiner LCW. In-phase and quadrature carrier intradyne signals C1, C2 are output at a first and second carrier recovery output CRO1, CRO2, respectively.

A third intradyne frequency divider IFD3 comprises a static intradyne frequency divider. As before, static intradyne frequency dividers undertake more than one state change while changing the phase of a carrier intradyne signal C1, C2 by 2π/N.

E.g., the polarities of the filtered intradyne part signals Zk are used for the asynchronous control of a finite state machine. For m=2 there are 4 possible polarities (Z1>0, Z2>0; or Z1>0, Z2<0; or Z1<0, Z2<0; or Z1<0, Z2>0). In that case the finite state machine could have just 4N different states, which does not allow for a sufficient accuracy. Z1, Z2, −Z1, −Z2 corresponding to m=2 may be understood to be 4 filtered intradyne part signals Zk with k=1, 2, 3, 4 according to m=4. For m≧3 the number of phases m can be doubled as follows: One employs the quantities Z1, (Z1+Z2)/(2*cos(ψₘ/2)), Z2, (Z2+Z3)/(2*cos(ψₘ/2)), Z3, (Z3+Z4)/(2*cos(ψₘ/2)), . . . , Zm, (Zm+Z1)/(2*cos(ψₘ/2)) as new filtered intradyne part signals Zo with o=1,2,3, . . . ,p, where p=2*m. This can be repeated several times if necessary. Different schemes for increasing the number of phase, for example a tripling or a multiplication by an arbitrary factor, are possible by taking suitable linear combinations of filtered intradyne part signals.

Let the filtered intradyne signal Z now be present in the form of p filtered intradyne part signals Zo (o=1,2, . . . ,p), where the number of phases p is larger than 4, for instance 8, 16, or 32. It is advantageous, to choose them equal to a power of 2 or equal to a power of 2, times 3. The o-th filtered intradyne part signal Zo represent Re(Z·e^{-j(o-1)ψ}_{ₚ}). The indices which refer to the filtered intradyne signal Z must in the following be understood in such a way that a value between 1 and p is chosen, modulo p.

Morover, an intradyne digital signal vector U is generated, with w=N·p intradyne digital part signals U1, U2, . . . , Uw as elements, each element being a binary digital signal. At any instant only one intradyne digital part signal Uv with v=1,2, . . . ,w is equal to 1, whereas the others are equal to 0. In the following the filtered intradyne part signals Zo are understood to be and processed as digital signals, where for positive or negative polarity of the analog the value 1 or 0 of the digital intradyne part signal Zo is chosen, respectively. The intradyne digital signal vector U is generated in a finite state machine which comprises w gates, each of which performs an operation

Uv=Zv [symbol] \overline{Z(v+1)} [symbol] \overline{U(v+p)} [symbol] \overline{U(v+2p)} [symbol] . . . [symbol] {overscore (U(v+(N−1)p))}.

Here it holds v=1,2, . . . ,w. Let the indices of intradyne digital part signals be transferred modulo w into that range 1,2, . . . ,w. The indices of filtered intradyne part signals must be understood in such a way that they are modulo p chosen between 1 and p. The indices of intradyne digital part signals must be understood in such a way that modulo w a value between and w is chosen. In the case that Zv [symbol] \overline{Z(v+1)} equals 1, the expectation value of the phase of the filtered intradyne signal Z is or should be equal to 2π((v−1/2)/p−1/4). The v-th intradyne digital part signal Uv represents therefore a phase 2π((v−1/2)/p−1/4+g)/N=2π((v−1/2)/w+(g−1/4)/N), where g=1,2, . . . ,N is possible.

The k-th in-phase intradyne part signal C1v is obtained by the analog operation

C1k=Σᵥ₌₁^{w}Uv·cos(2π((v−1/2)/w+(g−1/4)/N)−(o−1)ψₚ).

Likewise, the k-th quadrature intradyne part signal C2v is obtained by the analog operation

C2k=Σᵥ₌₁^{w}Uv·cos(2π((v−1/2)/w+(g−1/4)/N)−(o−1)ψₚ+π/2).

Since the intradyne digital part signals Uv are binary, only one summand is unequal zero here.

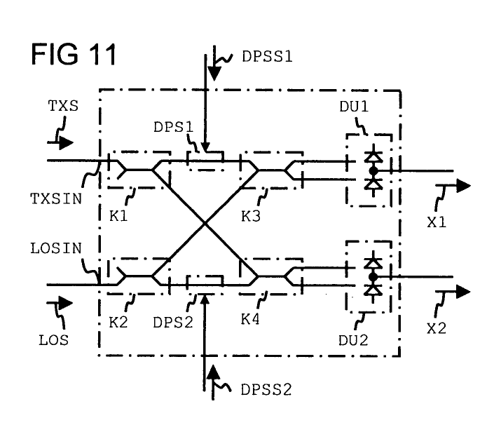

The detected intradyne signal X with a number of phases equal to m=2 or m=3 is generated for instance by means of an optical intradyne receiver which comprieses a local oscillator and an optoelectronic 90° hybrid or a 3×3 coupler, respectively. An embodiment of an optoelectronic hybrid OHY is shown in FIG. 11. Transmitted signal TXS and local oscillator signal LOS are connected at a transmitted signal input TXSIN and local oscillator signal input LOSIN, respectively. In a network of four couplers K1, K2, K3, K4 transmitted signal TXS and local oscillator signal LOS are superimposed with different phase relations. The output signals of the couplers K3, K4 are each detected in a detector unit DU1, DU2, respectively, where the first and second received intradyne part signal X1, X2 with the number of phases m=2 is generated, respectively. The phase relation, which is π/2 here, is adjusted by a differential phase shifter DPS1, DPS2, which is controlled by a phase shifter control signal DPSS1, DPSS2, respectively.

In order to avoid the necessity of adjusting equal polarizations of received optical signal and local oscillator one may realize two intradyne receivers, which form together a polarization diversity intradyne receiver. Suitable linear combinations of the received intradyne part signals provided by both intradyne receivers, corresponding to those linear cominations which an optical polarization control would have to perform with respect to field strengths, result in the desired detected intradyne signal X. A doubling of the transmission capacity with polarization division multiplex is likewise possible, where more linear combinations result in another detected intradyne signal with independent phase shift keying.

It is common to all embodiments of the intradyne frequency divider IFD1, IFD2, IFD3 that the phase of the carrier intradyne signal C1, C2 is modulo 2π, if at all, only quantized with steps having an absolute value smaller than 2π/N. In the case of the second intradyne frequency divider IFD2 this absolute value even is equal to zero because no quantization occurs in this analog unit.

It is also common to all embodiments of the intradyne frequency divider IFD1, IFD2, IFD3 that the phase of the carrier intradyne signal C1, C2 is modulo 2π quantized in more than N steps, In the case of the second intradyne frequency divider IFD2 the number of these steps tends toward infinity, because no quantization at all occurs in this analog unit.

The invention can also be adapted for phase step numbers N other than 2 or 4, for instance for N=8. This must be taken into account in the construction of the intradyne frequency multiplier and of the intradyne frequency divider IFD1, IFD2, IFD3. E.g., for N=8 the second intradyne frequency divider IFD2 may comprise three cascaded regenerative divide-by-2 intradyne frequency dividers of the type RIFD1, RIFD2, in order to achieve the overall necessary frequency division factor equal to N=8.

I claim:

1. A carrier recovery apparatus for a received intradyne signal that is phase shift keyed in N steps, where N is a phase step number, comprising:
an input for receiving a received intradyne signal;
a frequency multiplier for multiplying a frequency of the received intradyne signal by a factor of N, and thereby generating a frequency-multiplied intradyne signal;
a filter connected to said frequency multiplier, said filter filtering the frequency-multiplied intradyne signal to generate a filtered frequency-multiplied intradyne signal; and
an intradyne frequency divider connected to said filter, said intradyne frequency divider dividing the frequency of the filtered frequency-multiplied intradyne signal by a factor of N, thereby generating a carrier intradyne signal from the filtered frequency-multiplied intradyne signal, and said intradyne frequency divider undertaking more than one state change while changing a phase of the carrier intradyne signal by 2π/N.

2. The apparatus according to claim 1, wherein said intradyne frequency divider comprises:
a multi-frequency oscillator for generating a fundamental-frequency intradyne signal derivative having a fundamental frequency and a harmonic-frequency signal with a harmonic frequency being an N-fold multiple of the fundamental frequency;
a mixing unit for processing the filtered frequency-multiplied intradyne signal and the harmonic-frequency signal to generate a scalar product in which the frequency of the filtered frequency-multiplied intradyne signal has been translated by the N-fold of the fundamental frequency, wherein an absolute value of the fundamental frequency is so large that a scalar product can represent the filtered frequency-multiplied intradyne signal without loss of information;
a state machine, to which said scalar product is directed, said state machine dividing the frequency of the scalar product by N, thereby generating a frequency offset carrier signal; and
a multiplying unit for mixing the fundamental-frequency intradyne signal derivative and the frequency offset carrier signal, where the frequency of the frequency offset carrier signal is translated back by an amount equal to the fundamental frequency, thereby generating a carrier intradyne signal.

3. The apparatus according to claim 1, wherein said intradyne frequency divider comprises at least one regenerative intradyne frequency divider.

4. The apparatus according to claim 3, wherein a regenerative intradyne frequency divider comprises:
a complex multiplier for multiplying an intradyne input signal of said intradyne frequency divider and a complex conjugate intradyne signal; and
a complex conjugator for subjecting the intradyne output signal of said complex multiplier to a complex conjugation before it is being fed back as a complex conjugate intradyne signal to said complex multiplier.

5. The apparatus according to claim 3, wherein a regenerative intradyne frequency divider comprises:
a complex multiplier for multiplying an intradyne input signal of said intradyne frequency divider and a complex conjugate intradyne signal; and
a complex conjugator and a power raising unit cascaded with said complex conjugator in arbitrary order, wherein the intradyne output signal of said complex multiplier undergoes complex conjugation and is raised to a W-th power, W being a positive integer, before being fed back as a complex conjugate intradyne signal to said complex multiplier.

6. A carrier recovery method for a received intradyne signal that is phase shift keyed in N steps, where N is a phase step number, which comprises:
multiplying a frequency of the received intradyne signal by a factor N, thereby generating a frequency-multiplied intradyne signal from the received intradyne signal;
filtering the frequency-multiplied intradyne signal; and
dividing the frequency of the filtered frequency-multiplied intradyne signal by a factor N in an intradyne frequency divider, thereby generating a carrier intradyne signal from the filtered frequency-multiplied intradyne signal, in which process said intradyne frequency divider undertakes more than one state change while changing a phase of the carrier intradyne signal by 2π/N.

7. The method according to claim 6, which comprises:
generating a fundamental-frequency intradyne signal derivative having a fundamental frequency and a harmonic-frequency signal with a harmonic frequency, the harmonic frequency being an N-fold multiple of the fundamental frequency;
processing the filtered frequency-multiplied intradyne signal and the harmonic-frequency signal to generate a scalar product in which the frequency of the filtered frequency-multiplied intradyne signal has been translated by the N-fold of the fundamental frequency, wherein an absolute value of the fundamental frequency is so large that the scalar product can represent the filtered frequency-multiplied intradyne signal without loss of information;
dividing the frequency of the scalar product by N, thereby generating a frequency offset carrier signal; and
mixing the fundamental-frequency intradyne signal derivative and the frequency offset carrier signal, so that the frequency of said frequency offset carrier signal is translated back by an amount equal to the fundamental frequency, thereby generating a carrier intradyne signal.

8. The method according to claim 6, which comprises carrying out regenerative intradyne frequency dividing.

9. The method according to claim 8, which comprises:
complex-multiplying an intradyne input signal, the frequency of which is to be regeneratively divided, and a complex conjugate intradyne signal; and
complex-conjugating the regeneratively frequency divided intradyne signal to generate the complex conjugate intradyne signal.

10. The method according to claim 8, which comprises:
complex-multiplying an intradyne input signal, the frequency of which is to be regeneratively divided, and a complex conjugate intradyne signal; and
complex-conjugating and raising to a W-th power, W being a positive integer, of the regeneratively frequency divided intradyne signal to generate the complex conjugate intradyne signal.
